(19) United States
(12) Patent Application Publication
(10) Pub. No.: US 2003/0070757 A1
(43) Pub. Date: Apr. 17, 2003

(54) Method and apparatus for two-part CMP retaining ring

(76) Inventors: Dale E. DeMeyer, Cedar Park, TX (US); Larry D. Erwin, Cedar Park, TX (US); Raymond J. Hengel JR., Round Rock, TX (US); Carlos Madeira Leitao, Austin, TX (US)

Correspondence Address: Rick B. Yeager, 10805 Mellow Lane, Austin, TX, 78759, US

(21) Appl. No.: 10/237,531

(22) Filed: Sep. 6, 2002

Related U.S. Application Data
(60) Provisional application No. 60/318,238, filed on Sep. 7, 2001.

(51) Int. Cl. C23F 1/00; H01L 21/306

(52) U.S. Cl. 156/345.12; 156/345.14

(57) ABSTRACT

A two piece retaining ring used for chemical mechanical polishing of semiconductor substrates. The two pieces of the ring are secured to each other by means of a central thread on the first piece and a mating thread on the second piece.

### RELATED APPLICATIONS

This application claims priority from U.S. Provisional Application No. 60/318,238 filed Sep. 7, 2001 by Dale E. DeMeyer, Larry D. Erwin, Raymond J. Hengel, Jr., Carlos Madeira Leitao and Edward M. Nelson.

### FIELD OF INVENTION

This invention relates to a two part retaining ring typically used in chemical mechanical polishing operations.

### BACKGROUND

The present invention relates to a retaining ring used in the process of chemical mechanical polishing of semiconductor substrates. The substrate is typically a thin disc of semiconductor material with deposited alternate layers of conductive, semiconductive, and insulating materials. The layers are etched to produce electrical circuitry on the surface of the substrate. A typical substrate has a series of layers deposited and circuitry etched. The deposition and etching process after many layers produces a non flat top surface. This unflatness prevents accurate deposition of subsequent layers. Planarization of the substrate is periodically required to maintain an acceptable substrate surface. Chemical mechanical polishing of the topmost surface of the substrate produces a sufficiently flat surface to allow accurate subsequent deposition and etching of layers. This method of planarization is affected on a substrate by use of a polishing machine. Among the many subassemblies of this machine is the polishing head or carrier head. The polishing head contains among its components a retaining ring. This ring positions and retains the substrate allowing the other components of the head to exert pressure against the substrate which in turn moves relative to a polishing pad, usually wetted by a polishing medium or slurry.

The retaining ring is typically composed of two pieces. The first, or upper, piece is usually of a metal material such as stainless steel, aluminum, or molybdenum, but may be other materials. The second, or lower, piece is of a plastic material such as polyphenylene sulfide (PPS), polyethylene terephthalate, polyetheretherketone, polybutylene terephthalate or Ertalyte TX from Quadrant Engineering Plastic Products. U.S. Pat. No. 6,251,215 to Zuniga describes a two part chemical mechanical polishing (CMP) retaining ring where the first part is polyphenylene sulfide (PPS) and the second part is metal and the parts are joined by an epoxy adhesive. The '215 patent references, but does not describe, mating the first piece to the second piece by a plurality of individual screws.

The plastic portion of the ring is in physical contact with a polishing pad and slurry. Over a certain period of time the exposed surface of the ring is worn down due to the abrasiveness of the pad and slurry. Eventually the ring is no longer functional and must be replaced.

In prior art retaining rings, the entire worn ring must be removed from the polishing head and a new ring installed. This ring removing procedure is relatively expensive and time consuming as the ring is attached to the polishing head from inside the head. Therefore the head must be removed to gain access to the to the screws that fasten the ring to the head. The polishing machine must be taken offline to accomplish the ring replacement.

It is desirable to provide a method of replacing the plastic wear portion of the two part ring without removing the top portion from the carrier head. Replacing only the wear portion would reduce the maintenance time and complexity, lower part cost, and reduced shipping weight.

### SUMMARY

The invention is directed toward a method of fastening together two parts of a retaining ring used in the chemical mechanical polishing process of a semiconductor substrate. The first, or upper, part is typically a metal material such as stainless steel, aluminum, or molybdenum. The second, or lower, part is of a plastic material such as PPS.

One embodiment of the present invention is the use of a central single or multi lead left handed tread on the first metal piece so that the plastic piece may be threaded onto the metal piece. In one embodiment, a portion of the surface of the plastic material is inset to accept a threaded portion of the metal part. In another embodiment, a portion of the surface of the metal material is inset to accept a threaded portion of the plastic part.

The present invention permits less expensive replacement rings, and faster maintenance relative to prior art retaining rings.

### BRIEF DESCRIPTION OF THE DRAWINGS

These and other objects and advantages of the present invention are set forth below and further made clear by reference to the drawings, wherein:

FIG. 1A is a top view of the retaining ring.

FIG. 1B is a side view of the retaining ring.

FIG. 1C is a bottom view of the retaining ring.

FIG. 2 is an exploded view of the retaining ring.

FIG. 3A is an enlarged detail view of the first embodiment of the retaining ring detailing the central mating threads unassembled view.

FIG. 3B is an enlarged detail view of the first embodiment of the retaining ring detailing the central mating threads assembled view.

FIG. 4 is an exploded view of the retaining ring according to the second embodiment.

FIG. 5A is an enlarged detail view of the second embodiment of the central mating threads unassembled.

FIG. 5B is an enlarged detail view of the second embodiment of the central mating threads assembled.

FIG. 6A-FIG. 6C are details of various type of mating threads.

### DETAILED DESCRIPTION OF EMBODIMENT

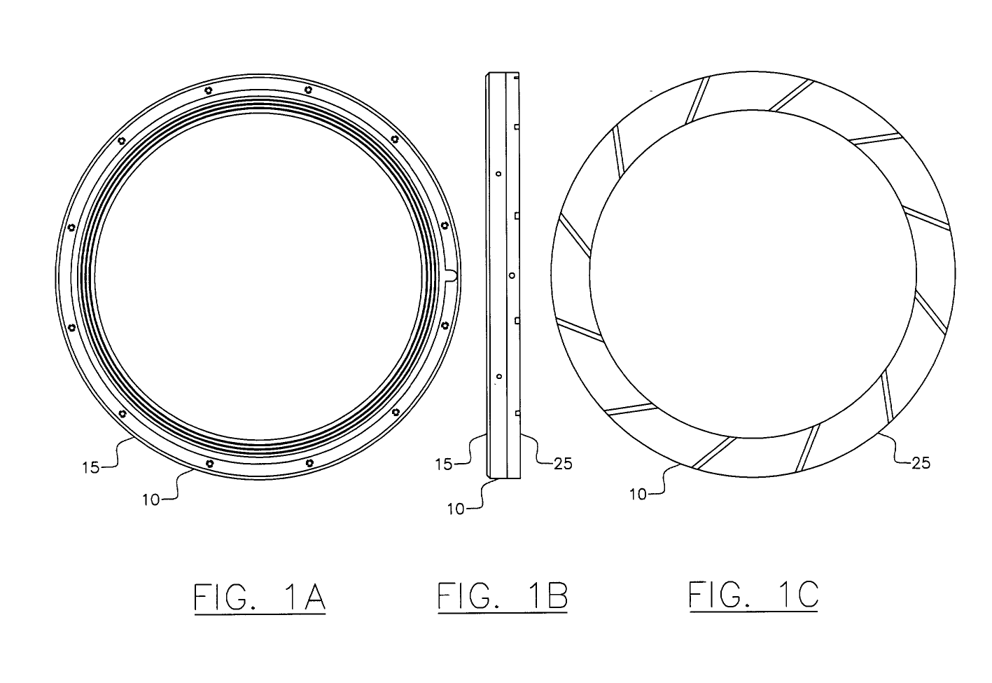

Referring now to FIGS. 1A-1C which are top, side and bottom view respectively of the two piece retaining ring 10 is composed of two parts, the first or upper part 15 is typically made of a metal, and the second or lower part 25 is typically made of plastic such as, polyphenylene sulfide (PPS), polyethylene terephthalate, polyetheretherketone, polybutylene terephthalate or Ertalyte TX.

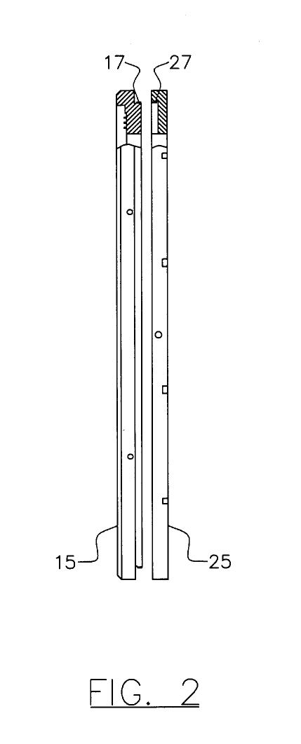

Referring now to FIG. 2, which is an exploded side view of the two part ring. In this embodiment the top part 15 is fastened to the bottom part 25 by means of a central female tread 27 and a mating male tread 17. The mated threads can be left handed or right handed.

As described below an alternate embodiment of the current invention fastens the second part to the first part by means of a central male tread.

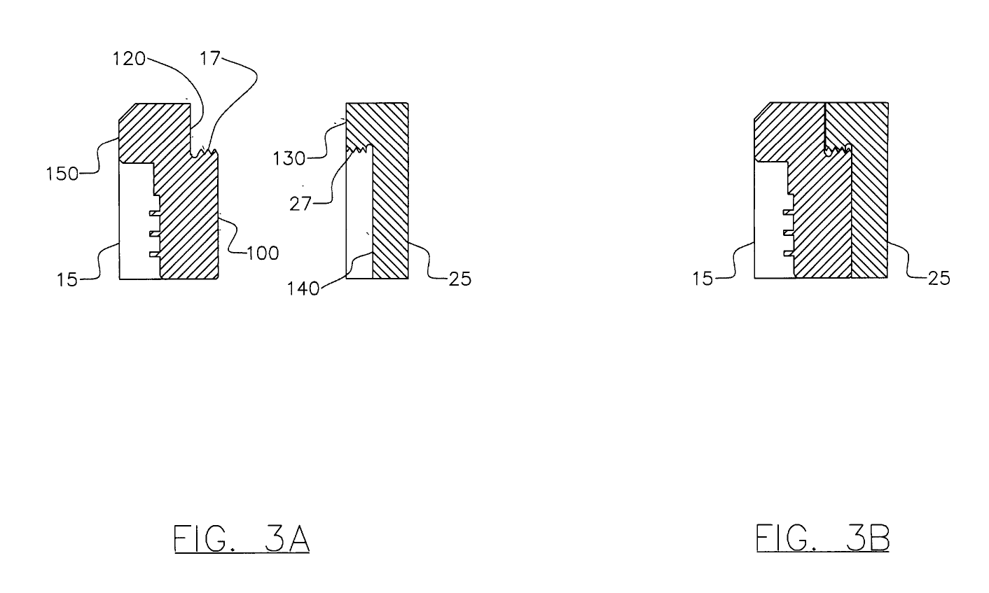

Referring now to FIGS. 3A and 3B which are enlarged unassembled and assembled detail views of the first embodiment of the retaining ring, the top part 15 is comprised of a first annular surface 100; a second annular surface 120 that is inset and located radially outward of the first surface; and a threaded edge surface 17 which connects the first surface and the second surface. It is not necessary for the entire edge surface to be threaded. The second bottom part 25 is comprised of a first annular surface 140 which is inset and located radially inward from a second annular surface 130; and a threaded edge surface 27 which connects the first surface and the second surface.

The top part 15 is typically mounted to a carrier head (not shown) by screws along its top surface 150. In this embodiment, the top part may remain on the carrier head while the lower part is replaced. In order to replace the lower part, it is unscrewed from the top part, and a replacement part is positioned on the threads. The lower part is then screwed onto the first part.

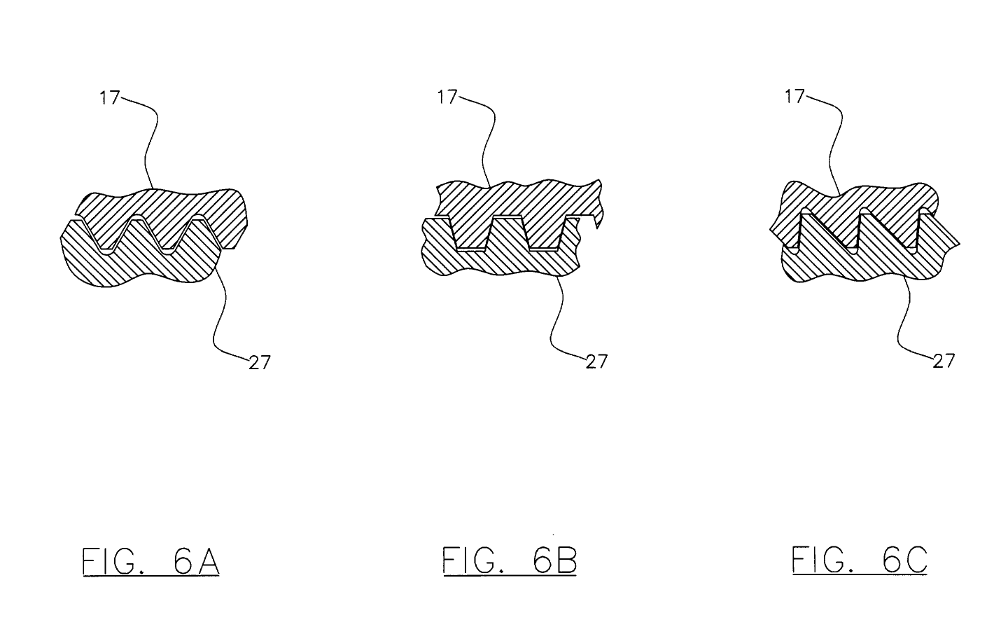

Referring now to FIGS. 6A-6B the mating tread can be of a single lead or a multi lead design. The form of the tread may be of a variety of types including but not limited to American Standard Unified Screw Thread, FIG. 6A, American National Unified Acme Screw Thread, FIG. 6B, and American National Standard Buttress Screw Thread, FIG. 6C.

In other embodiments, the thread form can also be of the Metric screw thread profile and may be of a custom non-standard design and specification.

The threads are of sufficient length to provide thread engagement that will provide the strength and stiffness required for the proper performance of the ring during the chemical mechanical polishing process.

In one embodiment, the first material is stainless steel and the second material is polyphenylene sulfide which includes TechTron® by DSM, Quadrant Engineering Plastic Products, Ryton® by Chevron-Phillips, and by Ensinger Corporation. In other embodiments, the second piece is a plastic material such as, polyethylene terephthalate, polyetheretherketone, polybutylene terephthalate or Ertalyte TX.

### DETAILED DESCRIPTION OF EMBODIMENT

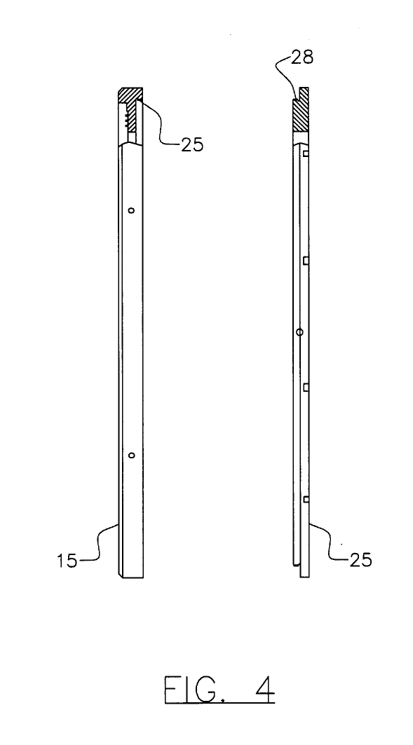

Referring now to FIG. 4 which is an exploded side view of the two part ring. An alternate embodiment of the current invention fastens the second part to the first part my means of a central male tread 28 on the second part 25 screwing in to the mating female tread 18 in the first part 15.

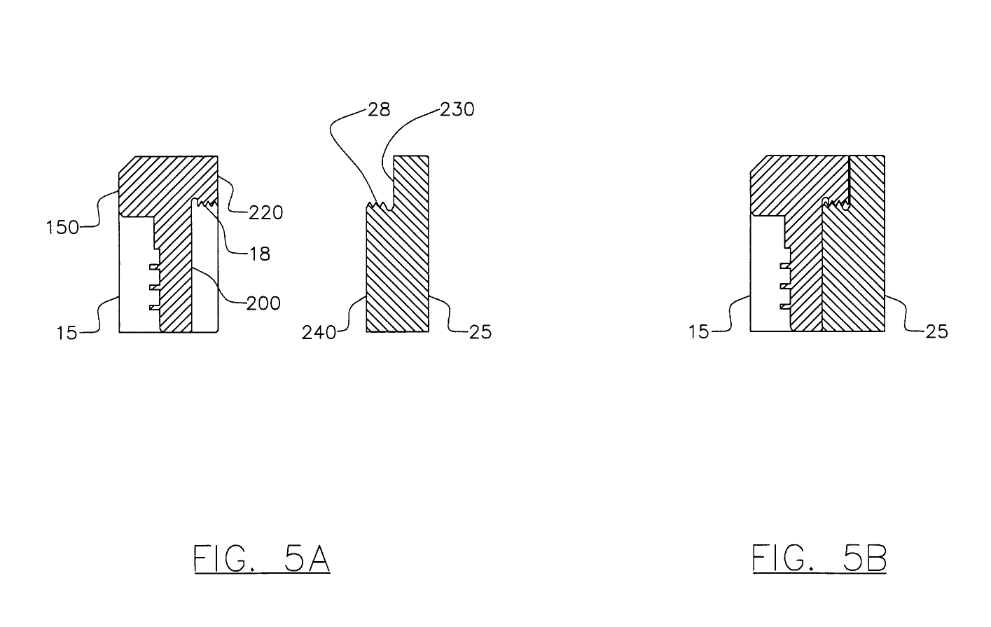

Referring now to FIGS. 5A and 5B which are an exploded and assembled detailed view of the mating treads. The central male tread 28 mates with the mating female tread 18.

Referring now to FIGS. 5A and 5B which are enlarged unassembled and assembled detail views of this embodiment of the retaining ring, the top part 15 is comprised of a first annular surface 200 which is inset and located radially inward from a second annular surface 220; and a threaded edge surface 18 which connects the first surface and the second surface. It is not necessary for the entire edge surface to be threaded. The second bottom part 25 is comprised of a first annular surface 240; a second annular surface 230 which is inset and located radially outward from the first annular surface; and a threaded edge surface 28 which connects the first surface and the second surface.

What is claimed is:

1. A retaining ring for a carrier head having a mounting surface for a substrate, the retaining ring comprising:
a first rigid annular portion comprising a mating surface, the mating surface comprising
an annular first level,
an annular second level offset from the first level, and
an edge surface connecting the first level and the second level, the edge surface being at least partially threaded; and
a second annular portion of a less rigid material than the first portion, the second portion comprising a mating surface, the mating surface comprising
an annular first level,
an annular second level offset from the first level, and
an edge surface connecting the first level and the second level, the edge surface being at least partially threaded such that the threaded edge surface of the first portion may be screwed together with the threaded edge surface of the second portion.

2. The retaining ring of claim 1 wherein
the second level of the first portion is inset from the first level of the first portion, and the second level of the first portion is located radially outward from the first level of the first portion; and
the first level of the second portion is inset from the second level of the second portion, and the second level of the second portion is located radially outward from the first level of the second portion.

3. The retaining ring of claim 1 wherein
the second level of the second portion is inset from the first level of the second portion, and the second level of the second portion is located radially outward from the first level of the second portion; and
the first level of the first portion is inset from the second level of the first portion, and the second level of the first portion is located radially outward from the first level of the first portion.

4. The retaining ring of claim 1 wherein
the edge surface of the first portion has a central multi-lead left handed thread.

5. The retaining ring of claim 1 wherein
the edge surface of the first portion has a central single lead left handed thread.

6. The retaining ring of claim 1 wherein
the first portion is a metal.

7. The retaining ring of claim 6 wherein
the first portion is selected from the group consisting of steel, aluminum, and molybdenum.

8. The retaining ring of claim 1 wherein
the second portion is a plastic.

9. The retaining ring of claim 8 wherein
the second portion is selected from the group consisting of polyphenylene sulfide, polyethylene terephthalate, polyetheretherketone, polybutylene terephthalate and Ertalyte TX.

10. The retaining ring of claim 1 wherein
the first portion is mounted on a carrier head; and
the second portion is replaceable without removing the first portion from the carrier head.

11. A retaining ring for a carrier head having a mounting surface for a substrate, the retaining ring comprising:
a means for securing a first rigid annular portion of the retaining ring to a carrier head; and
a means for screwing a second, less rigid than the first portion, annular portion of the retaining directly to the first portion.

12. A retaining ring for a chemical mechanical polishing retaining ring carrier head having a mounting surface for a substrate, the retaining ring comprising:
an upper metal annular portion, mountable on the carrier head, the metal portion comprising a mating surface, the mating surface comprising
an annular first level,
an annular second level offset from the first level, and
an edge surface connecting the first level and the second level, the edge surface being at least partially threaded with a left handed thread selected from the group consisting of single lead and multi-lead; and
a lower polyphenelene sulfide annular portion, removably screwed to the metal portion, the polyphenelene sulfide portion comprising a mating surface, the mating surface comprising
an annular first level,
an annular second level offset from the first level, and
an edge surface connecting the first level and the second level, the edge surface being at least partially threaded with a left handed thread selected from the group consisting of single lead and multi-lead, such that the threaded edge surface of the metal portion may be screwed together with the threaded edge surface of the polyphenelene sulfide portion.

13. A method of replacing the plastic wear portion of a two-part, metal and plastic, chemical mechanical polishing retaining ring for a carrier head, the method comprising
unscrewing the plastic wear portion from the metal portion of the ring while the metal portion remains mounted on the chemical mechanical polishing carrier head;
removing the plastic wear portion;
positioning a replacement plastic portion below the metal portion; and
screwing the replacement plastic portion onto the metal portion while the metal portion remains mounted on the chemical mechanical polishing carrier head.

14. The method of claim 13 further comprising
unscrewing, by means of left handed thread, the plastic wear portion from the metal portion of the ring while the metal portion remains mounted on the chemical mechanical polishing carrier head; and
screwing, by means of left handed thread, the replacement plastic portion onto the metal portion while the metal portion remains mounted on the chemical mechanical polishing carrier head.

15. A method of replacing the plastic wear portion of a two-part, metal and plastic, chemical mechanical polishing retaining ring for a carrier head, the method comprising
removing the retaining ring from the carrier head;
unscrewing the plastic wear portion from the metal portion of the ring;
removing the plastic wear portion;
positioning a replacement plastic portion below the metal portion;
screwing the replacement plastic portion onto the metal portion; and
replacing the retaining ring on the carrier head.

16. The method of claim 13 further comprising
unscrewing, by means of left handed thread, the plastic wear portion from the metal portion of the ring; and
screwing, by means of left handed thread, the replacement plastic portion onto the metal portion of the ring.
